(19) United States
(12) Patent Application Publication
(10) Pub. No.: US 2026/0125798 A1
(43) Pub. Date: May 7, 2026

(54) HIGH-THROUGHPUT PECVD SYSTEM APPLICABLE TO COATING MULTIPLE FILM LAYERS AND COATING PROCESS THEREOF

(71) Applicant: GOLD STONE (FUJIAN) ENERGY COMPANY LIMITED, Quanzhou (CN)

(72) Inventors: Yusheng YANG, Quanzhou (CN); Hongqing SHAN, Quanzhou (CN); Yijun LIU, Quanzhou (CN); Lixian GUO, Quanzhou (CN)

(73) Assignee: GOLD STONE (FUJIAN) ENERGY COMPANY LIMITED, Quanzhou (CN)

(21) Appl. No.: 19/062,132

(22) Filed: Feb. 25, 2025

(30) Foreign Application Priority Data
Nov. 7, 2024 (CN) 2024115782664

(51) Int. Cl. C23C 16/54; C23C 16/458; H10F 71/00

(52) U.S. Cl. CPC C23C 16/54; C23C 16/4583; H10F 71/137

(57) ABSTRACT

A high-throughput PECVD system applicable to coating multiple film layers and a coating process thereof are provided. The PECVD system includes a wafer inlet preheating chamber, a one-stop coating module and a cooling wafer outlet chamber connected in sequence through gate valves. The wafer inlet preheating chamber includes a wafer inlet-outlet stacking chamber and a heating plate, and the cooling wafer outlet chamber includes the wafer inlet-outlet stacking chamber and a cooling plate. The one-stop coating module includes an isolation chamber and several process chambers for coating different film layers, where the isolation chamber is provided between two adjacent process chambers through the gate valves; and each process chamber includes several deposition chambers that communicate with each other and can operate independently. The wafer inlet-outlet stacking chamber and the isolation chamber are both provided therein with a stack lifting mechanism.

### CROSS REFERENCE TO RELATED APPLICATIONS

This application claims the benefit of priority of Chinese Patent Application No. 2024115782664, filed 7 Nov. 2024. The contents of the above application is all incorporated by reference as if fully set forth herein in its entirety.

### TECHNICAL FIELD

The present disclosure relates to the field of photovoltaic devices, and particularly to a high-throughput PECVD system applicable to coating multiple film layers and a coating process thereof.

### BACKGROUND ART

The conventional plate-type PECVD equipment reduces equipment cycle and improves throughput of a single machine through a multi-stop deposition technique of a plurality of deposition chambers in series. Although this technique is a feasible cost-reducing technical route, with further research, shortcomings of the multi-stop deposition technique are found: the increase in the number of deposition chambers forces process deposition to be evenly divided by the cycle, thus affecting integrity of an amorphous/microcrystalline composite film layer deposition process of a certain functional layer and narrowing a process window. As shown in FIG. 5, the multi-stop deposition technique is used, that is, a silicon wafer is coated through multiple deposition chambers in a superimposed manner. As each chamber has a different process formula, in order to ensure stable connection (transition), each deposition chamber needs to be separately provided with a pump set 700 and a gate valve 600. Moreover, the multi-stop deposition technique has a fast feeding cycle, which results in a short time for assisting front and rear feeding and discharging. In order to ensure matching of operation cycle, a wafer inlet chamber 100, a preheating chamber 200, a process chamber 300, a cooling chamber 400, and a wafer outlet chamber 500 need to be provided in sequence in layout. As one chamber occupies a large area, more chambers not only increase the equipment cost, but also increase the occupied plant cost. Moreover, with use of the multi-stop deposition, when transferring a carrier plate in the process chamber, the gate valve 600 also needs to be opened and closed, which increases time for assisting deposition, and affects the throughput.

### SUMMARY

The present disclosure aims at providing a high-throughput PECVD system applicable to coating multiple film layers and a coating process thereof, which not only can shorten a length of a production line, save equipment and occupied land costs, but also improve throughput and efficiency.

In order to achieve the above objective, the present disclosure uses the following technical solutions.

The present disclosure discloses a high-throughput PECVD system applicable to coating multiple film layers, including a wafer inlet preheating chamber, a one-stop coating module and a cooling wafer outlet chamber which are connected in sequence through gate valves, where
the wafer inlet preheating chamber includes a wafer inlet-outlet stacking chamber and a heating plate, and the cooling wafer outlet chamber includes the wafer inlet-outlet stacking chamber and a cooling plate;
the one-stop coating module includes an isolation chamber and several process chambers for coating different film layers, where the isolation chamber is provided between two adjacent process chambers through the gate valves; and each process chamber includes several deposition chambers that communicate with each other and are capable of operating independently; and
the wafer inlet-outlet stacking chamber and the isolation chamber are both provided therein with a stack lifting mechanism.

Further, two kinds of the process chambers are provided, namely, an i-layer coating process chamber and a p-layer coating process chamber, respectively.

Further, the number of deposition chambers of the i-layer coating process chamber and the number of deposition chambers of the p-layer coating process chamber are equal.

Further, the number of deposition chambers of the i-layer coating process chamber and the number of deposition chambers of the p-layer coating process chamber are both four.

Further, the one-stop coating module further includes several evacuation pump sets, where one evacuation pump set communicates with one or more deposition chambers in the same process chamber.

Further, the wafer inlet-outlet stacking chamber includes a chamber body, a carrier-plate transmission mechanism, a stack lifting mechanism and a vacuum generator, where the carrier-plate transmission mechanism is provided at two sides of the chamber body; the stack lifting mechanism is provided in the wafer inlet preheating chamber in a vertically movable manner, the stack lifting mechanism is provided with several support spacers for placing the carrier plates, the support spacers are each provided with a heating plate or a cooling plate in a bottom, and the support spacers, the heating plates and the cooling plates are provided with avoidance regions for avoiding the carrier-plate transmission mechanism; when the stack lifting mechanism is lowered to a lowest point, the carrier-plate transmission mechanism is located above an uppermost support spacer, and when the stack lifting mechanism is lifted to a highest point, the carrier-plate transmission mechanism is located below a lowermost support spacer; and the vacuum generator is provided outside the chamber body.

Further, the carrier-plate transmission mechanism includes transmission wheels and a transmission driving member, where the transmission wheels are rotatably provided at two sides of the chamber body, the carrier plate is placed on the transmission wheels, and the transmission driving member is fixed outside the chamber body, and is in power connection with the transmission wheels for driving the transmission wheels to rotate.

Further, the stack lifting mechanism includes a lifting driving unit, a guide rod set and a carrier-plate storage frame, where the guide rod set has one end fixed to an upper end or a lower end of the chamber body, and the other end passing through the carrier-plate storage frame; the lifting driving unit is connected to the carrier-plate storage frame, for driving the carrier-plate storage frame to move up and down along the guide rod set; and the support spacer is located in the carrier-plate storage frame.

Further, the wafer inlet-outlet stacking chamber further includes a chamber body bracket, where the chamber body is fixed above the chamber body bracket, and the vacuum generator has one end communicating with a bottom of the chamber body, and the other end communicating with the outside.

Further, the stack lifting mechanism further includes a pull-up rod set, where lower ends of the pull-up rod set are respectively connected to an upper end surface of the carrier-plate storage frame at multiple points, and upper ends are connected to the lifting driving unit.

Further, the isolation chamber is the wafer inlet-outlet stacking chamber.

The present disclosure further discloses a coating process, using the above high-throughput PECVD system applicable to coating multiple film layers, including steps of:
S1, feeding and preheating: placing silicon wafers on all the carrier plates, stacking the silicon wafers into multiple layers; and conveying the carrier plates in batches onto the stack lifting mechanism of the wafer inlet preheating chamber for preheating;
S2, coating: conveying the preheated multi-layer carrier plates in batches into a first process chamber, coating a first film layer on the carrier plates in a one-step deposition mode; then conveying the multi-layer carrier plates in batches into the isolation chamber, after performing gas washing and vacuumizing, conveying the multi-layer carrier plates in batches into a second process chamber, coating a second film layer on the carrier plates in the one-step deposition mode, and coating several films similarly until completing a process of the coating; and
S3, cooling and discharging: conveying the coated carrier plates in batches onto the stack lifting mechanism of the cooling wafer outlet chamber for cooling, and after the cooling, conveying the carrier plates to an unloader to remove the silicon wafers.

Further, in the step S1, the silicon wafers are firstly placed on all the carrier plates through a loader, and stacked into multiple layers, the gate valve leading to the wafer inlet preheating chamber is opened, the multi-layer carrier plates are conveyed onto the stack lifting mechanism of the wafer inlet preheating chamber, the gate valve is closed, then gas washing and vacuumizing are performed on the wafer inlet preheating chamber until a vacuum degree and a process gas are consistent with those in the first process chamber, and at the same time, the silicon wafers on the carrier plates are heated.

Further, in the step S2, the gate valve leading to the process chamber is firstly opened, and the heated multi-layer carrier plates are conveyed layer by layer continuously to a lower part of each deposition chamber of the first process chamber by the stack lifting mechanism; the gate valve is closed, gas washing and vacuum breaking are performed on the wafer inlet preheating chamber, to remove the process gas and break the vacuum to room pressure, at the same time, each carrier plate in the first process chamber is lifted into corresponding deposition chamber to coat the first film layer, and at the same time, gas washing and vacuumizing are performed on the isolation chamber, until a vacuum degree and a process gas in the isolation chamber are consistent with those in the first process chamber;
after the first film layer is coated, the gate valve leading to the isolation chamber and the gate valve leading to the first process chamber are opened, each layer of the carrier plates after coating the first film layer is stacked onto the stack lifting mechanism in the isolation chamber by the stack lifting mechanism, at the same time, the carrier plates on the wafer inlet preheating chamber are conveyed on the first process chamber; the gate valves are closed, gas washing and vacuumizing are performed on the isolation chamber, until the vacuum degree and the process gas in the isolation chamber are consistent with those in the second process chamber; and at the same time, deposition electroplating is performed on the first process chamber; and
the gate valve leading to the second process chamber is opened, the multi-layer carrier plates in the isolation chamber are conveyed layer by layer continuously to a lower part of each deposition chamber of the second process chamber by the stack lifting mechanism; the gate valve is closed, gas washing and vacuumizing are performed on the isolation chamber, until the vacuum degree and the process gas in the isolation chamber are consistent with those in the first process chamber, and at the same time, each layer of the carrier plates in the second process chamber is lifted into corresponding deposition chamber to coat a second film layer, and several films are coated similarly until the process of the coating is completed.

Further, in the step S3, gas washing and vacuumizing are firstly performed on the cooling wafer outlet chamber until a vacuum degree and a process gas are consistent with those in an endmost process chamber, then the gate valve leading to the cooling wafer outlet chamber is opened, each layer of the carrier plates after coating the film layer is stacked onto the stack lifting mechanism in the cooling wafer outlet chamber by the stack lifting mechanism; the gate valve is closed, gas washing is performed on the cooling wafer outlet chamber to remove the process gas, and cooling and vacuum breaking are performed to room pressure; then the gate valve leading to the unloader is opened, the multi-layer carrier plates are conveyed in batches onto the unloader, the gate valve is closed, gas washing and vacuumizing are performed on the cooling wafer outlet chamber until the vacuum degree and the process gas are consistent with those in the endmost process chamber, and at the same time, the silicon wafers are removed through the unloader

The present disclosure has the following advantages.
1. The present disclosure uses the one-stop deposition structure to replace the existing multi-stop deposition technique, the deposition chambers in the process chamber communicate with each other and can operate independently; therefore, it is unnecessary to provide an evacuation pump set for each chamber, and exhaust pipelines of several deposition chambers can be connected in series to the same pump set through pipelines to perform evacuation and exhaust, thus reducing the number of pump sets and saving the cost. Moreover, the gate valve between the deposition chambers is omitted, so that auxiliary process time of the process chambers can be reduced, the equipment cycle is reduced, and the throughput is improved.
2. Moreover, the one-stop deposition structure performs long-cycle deposition, and front end and rear end feeding and discharging and pre-processing are prolonged, so that the chambers can be integrated, and the wafer inlet chamber and the preheating chamber, and the cooling chamber and the wafer outlet chamber in the prior art can be respectively functionally combined into the wafer inlet preheating chamber and the cooling wafer outlet chamber, thus reducing the number of chambers, shortening a length of production line, reducing an occupied land cost, and reducing equipment processing and manufacturing costs and installation period.
3. By providing the isolation chamber for isolating gas components between different process chambers, gas washing and vacuumizing can be performed in the isolation chamber, so as to realize deposition of different film layers in one line, and integrate the equipment, thus enabling the whole line equipment to be more compact, and reducing the occupied land area.

### BRIEF DESCRIPTION OF DRAWINGS

In order to more clearly illustrate technical solutions of embodiments of the present disclosure, drawings which need to be used in the embodiments will be briefly introduced below. It should be understood that the drawings merely show some embodiments of the present disclosure, and thus should not be considered as limitation to the scope, and those ordinarily skilled in the art still could obtain other relevant drawings according to these drawings, without using any inventive efforts.

FIG. 1 is a schematic view of the present embodiment.

FIG. 2 is a front cross-sectional view of the present embodiment.

FIG. 3 is a cross-sectional side view of a wafer inlet-outlet stacking chamber.

FIG. 4 is a schematic view of an avoidance region.

FIG. 5 is a view of prior art in BACKGROUND ART.

### DESCRIPTION OF REFERENCE SIGNS OF MAIN ELEMENTS

1, wafer inlet preheating chamber;
2, one-stop coating module; 21, i-layer coating process chamber; 211, first i-layer coating deposition chamber; 212, second i-layer coating deposition chamber; 213, third i-layer coating deposition chamber; 214, fourth i-layer coating deposition chamber; 22, p-layer coating process chamber; 221, first p-layer coating deposition chamber; 222, second p-layer coating deposition chamber; 223, third p-layer coating deposition chamber; 224, fourth p-layer coating deposition chamber; 25, evacuation pump set;
3, cooling wafer outlet chamber;
4, wafer inlet-outlet stacking chamber; 41, chamber body bracket; 42, chamber body; 43, carrier-plate transmission mechanism; 431, transmission wheel; 432, transmission driving member; 44, stack lifting mechanism; 441, support spacer; 442, avoidance region; 443, lifting driving unit; 444, pull-up rod set; 445, guide rod set; 446, carrier-plate storage frame; 45, vacuum generator;
5, heating plate;
6, cooling plate;
7, isolation chamber;
81, first gate valve; 82, second gate valve; 83, third gate valve; 84, fourth gate valve; 85, fifth gate valve; 86, sixth gate valve.

### DETAILED DESCRIPTION OF EMBODIMENTS

In order to make objectives, technical solutions and advantages of embodiments of the present disclosure clearer, technical solutions in the embodiments of the present disclosure will be described clearly and completely below in conjunction with the drawings in the description. Apparently, only some but not all embodiments of the present disclosure are described. Based on the embodiments in the present disclosure, all of other embodiments obtained by those ordinarily skilled in the art without using any inventive efforts shall fall within the scope of protection of the present disclosure.

In the present disclosure, unless otherwise specified, directional terms such as “upper, lower, left, and right” are generally understood in conjunction with orientation shown in the drawings and practical application.

Besides, the terms “first” and “second” are merely used for descriptive purpose, but should not be construed as indicating or implying importance in the relativity or implicitly indicating the number of a related technical feature. Thus, defining a feature with “first” or “second” may explicitly or implicitly mean that one or more such features are included. In the description of the present disclosure, “a plurality of” means two or more, unless otherwise explicitly defined.

In the present disclosure, unless otherwise explicitly specified and defined, a first feature being “on” or “under” a second feature may mean that the first feature is in direct contact with the second feature, or the first feature is in indirect contact with the second feature via an intermediary. Moreover, the first feature being “over”, “above” and “on top of” the second feature may be the case that the first feature is directly above or not directly above the second feature, or only means that the first feature is at a horizontal height higher than the second feature. The first feature being “under”, “beneath” or “below” a second feature may include a case where the first feature is directly below or not directly below the second feature, or only means that the first feature is at a horizontal height lower than the second feature.

Endpoints and any value of ranges disclosed herein are not limited to the precise ranges or values, and these ranges or values should be understood as encompassing values close to these ranges or values. For numerical ranges, endpoint values of various ranges can be combined with each other, endpoint values of various ranges and individual point values can be combined with each other, and individual point values can be combined with each other to obtain one or more new numerical ranges, and such numerical ranges should be construed as being specifically disclosed herein. The terms “optional” and “optionally” both mean possibly including or not (or possibly being present or possibly being not present).

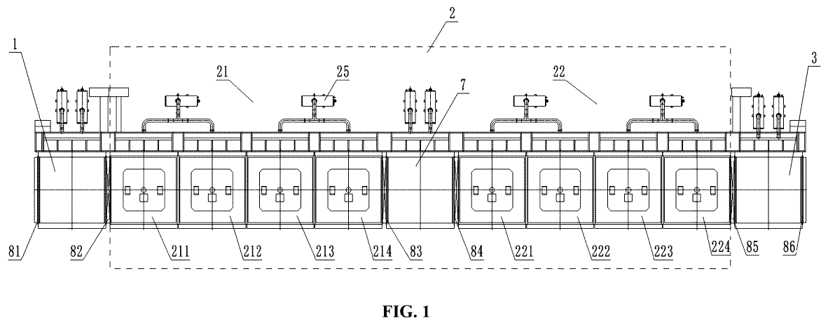

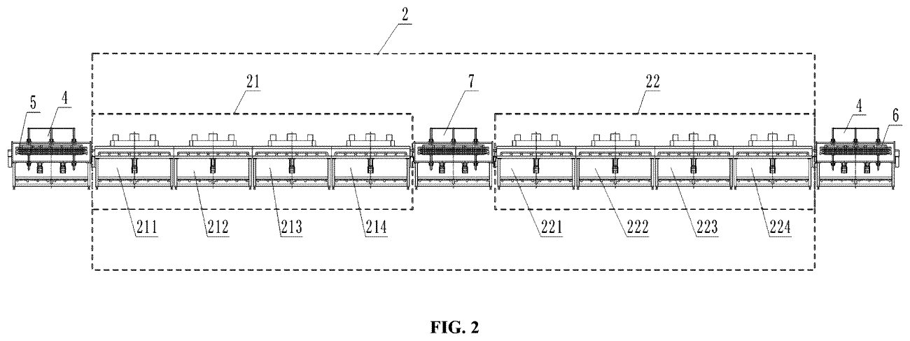

As shown in FIG. 1 to FIG. 4, the present disclosure discloses a high-throughput PECVD system applicable to coating multiple film layers, including a wafer inlet preheating chamber 1, a one-stop coating module 2 and a cooling wafer outlet chamber 3 connected in sequence through gate valves.

The one-stop coating module 2 includes an isolation chamber 7, an evacuation pump set 25 and several process chambers for coating different film layers. The isolation chamber 7 is provided between two adjacent process chambers through the gate valves. Each process chamber includes several deposition chambers that communicate with each other and can operate independently. One evacuation pump set 25 communicates with one or more deposition chambers in the same process chamber.

The wafer inlet preheating chamber 1 includes a wafer inlet-outlet stacking chamber 4 and a heating plate 5. The cooling wafer outlet chamber 3 includes the wafer inlet-outlet stacking chamber 4 and a cooling plate 6. The wafer inlet-outlet stacking chamber 4 and the isolation chamber 7 are both provided therein with a stack lifting mechanism 44.

In the present embodiment, two kinds of process chambers are provided, namely, an i-layer coating process chamber 21 for coating an intrinsic silicon passivation layer and a p-layer coating process chamber 22 for coating a p-type silicon doped layer, respectively. The isolation chamber 7 is provided between the i-layer coating process chamber 21 and the p-layer coating process chamber 22. The isolation chamber 7 adopts the wafer inlet-outlet stacking chamber 4.

In the above, the number of deposition chambers of the i-layer coating process chamber 21 and the number of deposition chambers of the p-layer coating process chamber 22 are equal, both being four, namely, a first i-layer coating deposition chamber 211, a second i-layer coating deposition chamber 212, a third i-layer coating deposition chamber 213 and a fourth i-layer coating deposition chamber 214, and a first p-layer coating deposition chamber 221, a second p-layer coating deposition chamber 222, a third p-layer coating deposition chamber 223 and a fourth p-layer coating deposition chamber 224, respectively.

Therefore, the PECVD system in the present embodiment includes a loader, the wafer inlet preheating chamber 1, the first i-layer coating deposition chamber 211, the second i-layer coating deposition chamber 212, the third i-layer coating layer deposition chamber 213, the fourth i-layer coating deposition chamber 214, the isolation chamber 7, the first p-layer coating deposition chamber 221, a second p-layer coating deposition chamber 222, a third p-layer coating deposition chamber 223, a fourth p-layer coating deposition chamber 224, the cooling wafer outlet chamber 3 and an unloader connected in sequence.

In the above, the gate valves, namely, a first gate valve 81, a second gate valve 82, a third gate valve 83, a fourth gate valve 84, a fifth gate valve 85, and a sixth gate valve 86 respectively, are provided between the loader and the wafer inlet preheating chamber 1, between the wafer inlet preheating chamber 1 and the first i-layer coating deposition chamber 211, between the fourth i-layer coating deposition chamber 214 and the isolation chamber 7, between the isolation chamber 7 and the first p-layer coating deposition chamber 221, between the fourth p-layer coating deposition chamber 224 and the cooling wafer outlet chamber 3, and between the cooling wafer outlet chamber 3 and the unloader.

The first i-layer coating deposition chamber 211, the second i-layer coating deposition chamber 212, the third i-layer coating deposition chamber 213, and the fourth i-layer coating deposition chamber 214 communicate with each other and can operate independently.

The first p-layer coating deposition chamber 221, the second p-layer coating deposition chamber 222, the third p-layer coating deposition chamber 223, and the fourth p-layer coating deposition chamber 224 communicate with each other and can operate independently.

The multi-stop process chamber in the prior art has a short-cycle deposition structure, that is, a plurality of deposition chambers collectively deposit one carrier plate, so that the carrier plate resides in the deposition chambers for a short time, and there is short time for front and rear end feeding and discharging and pre-processing; therefore, a plurality of pre-processing chambers need to be provided to reduce pre-processing time.

The one-stop process chamber designed in the present embodiment has a long-cycle deposition structure, that is, each deposition chamber independently deposits one carrier plate, and a plurality of carrier plates are simultaneously deposited, so as to reserve a relatively long auxiliary time for front and rear end feeding and discharging and pre-processing, so that the wafer inlet chamber and the preheating chamber, and the cooling chamber and the wafer outlet chamber in the prior art can be respectively functionally combined into the wafer inlet preheating chamber 1 and the cooling wafer outlet chamber 3, thus reducing the number of chambers, shortening a length of production line, reducing an occupied land cost, and reducing equipment processing and manufacturing costs and installation period.

Moreover, the process chamber uses a one-stop deposition structure to replace the multi-stop deposition technique, and the gate valve between the deposition chambers is omitted. As a plurality of deposition chambers of the one-stop process chamber communicate with each other, and have a consistent gas formula, it is unnecessary to provide an evacuation pump set 25 for each chamber, and several deposition chambers can be connected in series to the same pump set through exhaust pipelines to perform evacuation and exhaust, thus reducing the number of pump sets and saving the cost. The gate valve between the deposition chambers is omitted, so that auxiliary process time of the process chambers can also be reduced, the equipment cycle is reduced, and the throughput is improved.

By providing the isolation chamber 7 between different process chambers for isolating gas components between different process chambers, gas washing and vacuumizing can be performed in the isolation chamber 7, so as to realize deposition of different film layers in one line, and integrate the equipment, thus enabling the whole line equipment to be more compact, and reducing the occupied land area.

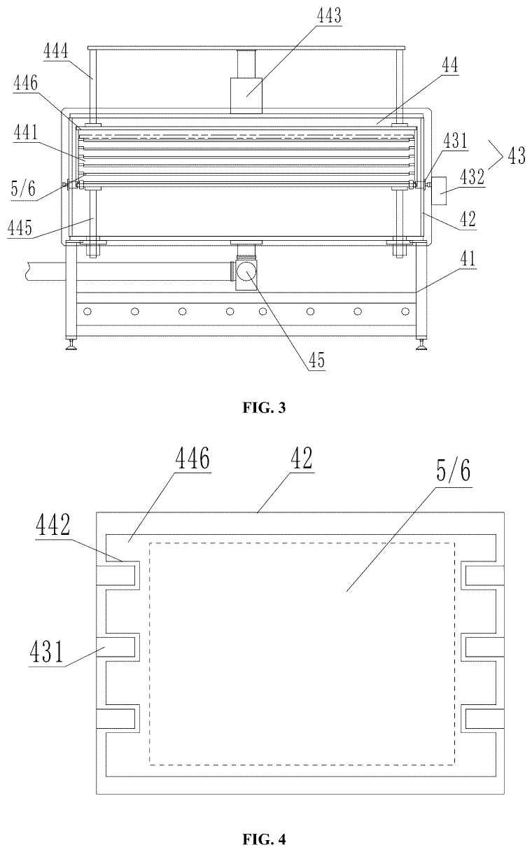

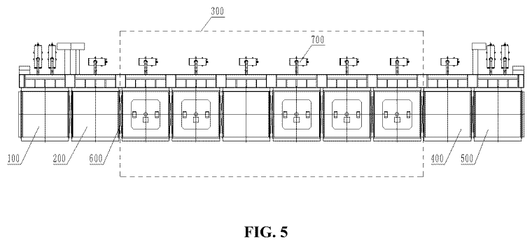

Specifically, as shown in FIG. 3 and FIG. 4, the wafer inlet-outlet stacking chamber 4 includes a chamber body bracket 41, a chamber body 42, a carrier-plate transmission mechanism 43, a stack lifting mechanism 44 and a vacuum generator 45.

In the above, the carrier-plate transmission mechanism 43 is provided on the chamber body 42 and is configured to transport the carrier plate to a station of the stack lifting mechanism 44. Specifically, the carrier-plate transmission mechanism 43 includes transmission wheels 431 and a transmission driving member 432, where the transmission wheels 431 are rotatably provided at two sides of the chamber body 42, the carrier plate is placed on the transmission wheels 431, and the transmission driving member 432 is fixed outside the chamber body 42, and is in power connection with the transmission wheels 431, for driving the transmission wheels 431 to rotate.

In the above, the stack lifting mechanism 44 is provided in the wafer inlet preheating chamber 1 in a vertically movable manner. The stack lifting mechanism 44 is provided with several support spacers 441 for placing the carrier plates, the support spacers 441 are each provided with a heating plate 5 or a cooling plate 6 in a bottom, and the support spacers 441, the heating plates 5 and the cooling plates 6 are provided with avoidance regions 442 for avoiding the transmission wheels 431 of the carrier-plate transmission mechanism 43. When the stack lifting mechanism 44 is lowered to the lowest point, the transmission wheels 431 are located above an uppermost support spacer 441, and when the stack lifting mechanism 44 is lifted to the highest point, the transmission wheels 431 are located below a lowermost support spacer 441. Specifically, the stack lifting mechanism 44 includes a lifting driving unit 443, a pull-up rod set 444, a guide rod set 445 and a carrier-plate storage frame 446. The guide rod set 445 has one end fixed to an upper end or a lower end of the chamber body 42, and the other end passing through the carrier-plate storage frame 446. The guide rod set 445 in the present embodiment is provided at the lower end of the chamber body 42.

Lower ends of the pull-up rod set 444 are respectively connected to an upper end surface of the carrier-plate storage frame 446 at multiple points, and upper ends are connected to the lifting driving unit 443, for driving the carrier-plate storage frame 446 to move up and down along the guide rod set 445. By providing the pull-up rod set 444, the carrier-plate storage frame 446 can be subjected to a more uniform force. The support spacer 441 is located in the carrier-plate storage frame 446.

In the above, the chamber body 42 is fixed above the chamber body bracket 41, and the vacuum generator 45 has one end communicating with a bottom of the chamber body 42, and the other end communicating with the outside.

In use, the carrier-plate storage frame 446 is firstly lowered to the lowest point, and the carrier-plate transmission mechanism 43 conveys the carrier plate to above the carrier-plate storage frame 446, and the carrier-plate storage frame 446 is driven by the lifting driving unit 443 to move upwards, picks up the carrier plate, and stores the carrier plate in the support spacer 441, until the several support spacers 441 are all filled with the carrier plates. Then the gate valve is closed and preheating is performed. After the preheating, the carrier-plate storage frames 446 are lowered in sequence, the carrier plates are transferred in batches through the carrier-plate transmission mechanism 43 into various deposition chambers of the process chamber for independent deposition. After the deposition is completed, by the same principle, by lifting up and down the carrier-plate storage frames 446 in the cooling wafer outlet chamber 3, the carrier plates are cooled and conveyed to the next process.

The present embodiment further discloses a coating process, which uses the above high-throughput PECVD system applicable to coating multiple film layers, including the following steps:
S1, feeding and preheating: placing the silicon wafers on all the carrier plates through the loader, stacking the silicon wafers into multiple layers, opening the first gate valve 81 leading to the wafer inlet preheating chamber 1, conveying multi-layer carrier plates onto the stack lifting mechanism 44 of the wafer inlet preheating chamber 1, closing the first gate valve 81, then performing gas washing and vacuumizing on the wafer inlet preheating chamber 1 until a vacuum degree and a process gas being consistent with those in the i-layer coating process chamber 21, and at the same time, heating the silicon wafers on the carrier plates;
S2, coating: opening the second gate valve 82 leading to the i-layer coating process chamber 21, and conveying the heated multi-layer carrier plates layer by layer continuously to a lower part of each deposition chamber of the i-layer coating process chamber 21 by the stack lifting mechanism 44; closing the second gate valve 82, performing gas washing and vacuum breaking on the wafer inlet preheating chamber 1, to remove the process gas and break the vacuum to room pressure, at the same time, lifting each carrier plate in the i-layer coating process chamber 21 into corresponding deposition chamber to coat a first film layer, and at the same time, performing gas washing and vacuumizing on the isolation chamber 7, until a vacuum degree and a process gas in the isolation chamber 7 being consistent with those in the i-layer coating process chamber 21;
after coating the first film layer, opening the third gate valve 83 leading to the isolation chamber 7 and the second gate valve 82 leading to the i-layer coating process chamber 21, stacking each layer of the carrier plates after coating the first film layer onto the stack lifting mechanism 44 in the isolation chamber 7 by the stack lifting mechanism 44, at the same time, conveying the carrier plates in the wafer inlet preheating chamber 1 into the i-layer coating process chamber 21; closing the third gate valve 83 and the second gate valve 82, performing gas washing and vacuumizing on the isolation chamber 7, until the vacuum degree and the process gas in the isolation chamber 7 being consistent with those in the p-layer coating process chamber 22; and at the same time, performing deposition electroplating in the i-layer coating process chamber 21;
opening the fourth gate valve 84 leading to the p-layer coating process chamber 22, conveying multi-layer carrier plates in the isolation chamber 7 layer by layer continuously to a lower part of each deposition chamber of the p-layer coating process chamber 22 by the stack lifting mechanism 44; closing the fourth gate valve 84, performing gas washing and vacuumizing on the isolation chamber 7, until the vacuum degree and the process gas in the isolation chamber 7 being consistent with those in the i-layer coating process chamber 21, and at the same time, lifting each carrier plate in the p-layer coating process chamber 22 into corresponding deposition chamber to coat a second film layer; and
S3, cooling and discharging: performing gas washing and vacuumizing on the cooling wafer outlet chamber 3 until a vacuum degree and a process gas being consistent with those in the p-layer coating process chamber 22, then opening the fifth gate valve 85 leading to the cooling wafer outlet chamber 3, stacking each layer of the carrier plates after coating the film layer onto the stack lifting mechanism 44 in the cooling wafer outlet chamber 3 by the stack lifting mechanism 44; closing the fifth gate valve 85, performing gas washing on the cooling wafer outlet chamber 3 to remove the process gas, cooling and breaking vacuum to room pressure; then, opening the sixth gate valve 86 leading to the unloader, conveying multi-layer carrier plates in batches onto the unloader, closing the sixth gate valve 86, performing gas washing and vacuumizing on the cooling wafer outlet chamber 3 until the vacuum degree and the process gas being consistent with those in an endmost process chamber, and at the same time, removing the silicon wafers through the unloader.

After the carrier plates in the wafer inlet preheating chamber 1 are conveyed into the i-layer coating process chamber 21, and the gate valve is closed, when the i-layer coating process chamber 21 starts the deposition coating: the loader places the silicon wafers on all the carrier plates, and waits to convey the carrier plates into the wafer inlet preheating chamber. At the same time, the gas washing and vacuum breaking are performed on the wafer inlet preheating chamber 1, the wafer inlet preheating chamber 1 receives the carrier plates from the loader, the gas washing, vacuumizing, and heating are performed on the wafer inlet preheating chamber 1, and the wafer inlet preheating chamber 1 waits to convey the carrier plates into the i-layer coating process chamber 21 (gas washing, vacuum breaking→receiving the carrier plates from the loader→gas washing, vacuumizing, heating, waiting to convey the carrier plates into the i-layer coating process chamber 21). At the same time, the gas washing and vacuumizing are performed on the isolation chamber 7, the isolation chamber 7 conveys the carrier plates into the p-layer coating process chamber 22, the gas washing and vacuumizing are performed on the isolation chamber 7, and the isolation chamber 7 waits to receive the carrier plates from the i-layer coating process chamber 21 (gas washing, vacuumizing→conveying the carrier plates into the p-layer coating process chamber 22→gas washing, vacuumizing, waiting to receive the carrier plates from the i-layer coating process chamber 21).

After the carrier plates in the isolation chamber 7 are conveyed into the p-layer coating process chamber 22, and the gate valve is closed, when the p-layer coating process chamber 22 starts the deposition coating: at the same time, the gas washing, vacuum breaking, and cooling are performed on the cooling wafer outlet chamber 3, the cooling wafer outlet chamber 3 conveys the carrier plates to the unloader, the gas washing and vacuum breaking are performed on the cooling wafer outlet chamber 3, and the cooling wafer outlet chamber 3 waits to receive the carrier plates from the p-layer coating process chamber 22 (gas washing, vacuum breaking, cooling→conveying the carrier plates to the unloader→gas washing, vacuumizing, waiting to receive the carrier plates from the p-layer coating process chamber 22). The unloader removes the silicon wafers from the carrier plates, and waits to receive the carrier plates from the cooling wafer outlet chamber 3.

To sum up, the present disclosure not only can shorten the length of the production line, and save equipment and occupied land costs, but also can improve the throughput and efficiency.

Preferred embodiments of the present disclosure are described in detail in the above, but the present disclosure is not limited thereto. Within the scope of technical concept of the present disclosure, a number of simple modifications can be made to the technical solutions of the present disclosure, including combining various technical features in any other suitable ways, and these simple modifications and combinations should also be regarded as the contents disclosed in the present disclosure, and all fall within the scope of the present disclosure.

What is claimed is:

1. A high-throughput PECVD system applicable to coating multiple film layers, comprising a wafer inlet preheating chamber, a one-stop coating module and a cooling wafer outlet chamber which are connected in sequence through gate valves, wherein
the wafer inlet preheating chamber comprises a wafer inlet-outlet stacking chamber and a heating plate, and the cooling wafer outlet chamber comprises the wafer inlet-outlet stacking chamber and a cooling plate;
the one-stop coating module comprises an isolation chamber and several process chambers for coating different film layers, wherein the isolation chamber is provided between two adjacent process chambers through the gate valves; and each process chamber comprises several deposition chambers that communicate with each other and are capable of operating independently; and
the wafer inlet-outlet stacking chamber and the isolation chamber are both provided therein with a stack lifting mechanism.

2. The high-throughput PECVD system applicable to coating multiple film layers according to claim 1, wherein two kinds of the process chambers are provided, which are an i-layer coating process chamber and a p-layer coating process chamber, respectively.

3. The high-throughput PECVD system applicable to coating multiple film layers according to claim 1, wherein the number of deposition chambers of the i-layer coating process chamber and the number of deposition chambers of the p-layer coating process chamber are equal.

4. The high-throughput PECVD system applicable to coating multiple film layers according to claim 3, wherein the number of deposition chambers of the i-layer coating process chamber and the number of deposition chambers of the p-layer coating process chamber are both four.

5. The high-throughput PECVD system applicable to coating multiple film layers according to claim 1, wherein the one-stop coating module further comprises several evacuation pump sets, wherein one evacuation pump set communicates with one or more deposition chambers in the same process chamber.

6. The high-throughput PECVD system applicable to coating multiple film layers according to claim 1, wherein the wafer inlet-outlet stacking chamber comprises a chamber body, a carrier-plate transmission mechanism, a stack lifting mechanism and a vacuum generator, wherein the carrier-plate transmission mechanism is provided at two sides of the chamber body; the stack lifting mechanism is provided in the wafer inlet preheating chamber in a vertically movable manner, the stack lifting mechanism is provided with several support spacers for placing the carrier plates, the support spacers are each provided with a heating plate or a cooling plate in a bottom, and the support spacers, the heating plates and the cooling plates are provided with avoidance regions for avoiding the carrier-plate transmission mechanism; when the stack lifting mechanism is lowered to a lowest point, the carrier-plate transmission mechanism is located above an uppermost support spacer, and when the stack lifting mechanism is lifted to a highest point, the carrier-plate transmission mechanism is located below a lowermost support spacer; and the vacuum generator is provided outside the chamber body.

7. The high-throughput PECVD system applicable to coating multiple film layers according to claim 6, wherein the carrier-plate transmission mechanism comprises transmission wheels and a transmission driving member, wherein the transmission wheels are rotatably provided at two sides of the chamber body, the carrier plate is placed on the transmission wheels, and the transmission driving member is fixed outside the chamber body, and is in power connection with the transmission wheels for driving the transmission wheels to rotate.

8. The high-throughput PECVD system applicable to coating multiple film layers according to claim 6, wherein the stack lifting mechanism comprises a lifting driving unit, a guide rod set and a carrier-plate storage frame, wherein the guide rod set has one end fixed to an upper end or a lower end of the chamber body, and the other end passing through the carrier-plate storage frame; the lifting driving unit is connected to the carrier-plate storage frame, for driving the carrier-plate storage frame to move up and down along the guide rod set; and the support spacer is located in the carrier-plate storage frame.

9. The high-throughput PECVD system applicable to coating multiple film layers according to claim 6, wherein the wafer inlet-outlet stacking chamber further comprises a chamber body bracket, wherein the chamber body is fixed above the chamber body bracket, and the vacuum generator has one end communicating with a bottom of the chamber body, and the other end communicating with outside.

10. The high-throughput PECVD system applicable to coating multiple film layers according to claim 6, wherein the stack lifting mechanism further comprises a pull-up rod set, wherein lower ends of the pull-up rod set are respectively connected to an upper end surface of the carrier-plate storage frame at multiple points, and upper ends are connected to the lifting driving unit.

11. The high-throughput PECVD system applicable to coating multiple film layers according to claim 6, wherein the isolation chamber is the wafer inlet-outlet stacking chamber.

12. A coating process, using the high-throughput PECVD system applicable to coating multiple film layers according to claim 1, comprising steps of:
S1, feeding and preheating: placing silicon wafers on all the carrier plates, stacking the silicon wafers into multiple layers; and conveying the carrier plates in batches onto the stack lifting mechanism of the wafer inlet preheating chamber for preheating;
S2, coating: conveying the preheated multi-layer carrier plates in batches into a first process chamber, coating a first film layer on the carrier plates in a one-step deposition mode; then conveying the multi-layer carrier plates in batches into the isolation chamber, after performing gas washing and vacuumizing, conveying the multi-layer carrier plates in batches into a second process chamber, coating a second film layer on the carrier plates in the one-step deposition mode, and coating several films similarly until completing the coating process; and
S3, cooling and discharging: conveying the coated carrier plates in batches onto the stack lifting mechanism of the cooling wafer outlet chamber for cooling, and after the cooling, conveying the carrier plates to an unloader to remove the silicon wafers.

13. The coating process according to claim 12, wherein in the step S1, the silicon wafers are firstly placed on all the carrier plates through a loader, and stacked into multiple layers, the gate valve leading to the wafer inlet preheating chamber is opened, the multi-layer carrier plates are conveyed onto the stack lifting mechanism of the wafer inlet preheating chamber, the gate valve is closed, then gas washing and vacuumizing are performed on the wafer inlet preheating chamber until a vacuum degree and a process gas are consistent with those in the first process chamber, and at the same time, the silicon wafers on the carrier plates are heated.

14. The coating process according to claim 13, wherein in the step S2, the gate valve leading to the process chamber is firstly opened, and the heated multi-layer carrier plates are conveyed layer by layer continuously to a lower part of each deposition chamber of the first process chamber by the stack lifting mechanism; the gate valve is closed, gas washing and vacuum breaking are performed on the wafer inlet preheating chamber, to remove the process gas and break the vacuum to room pressure, at the same time, each carrier plate in the first process chamber is lifted into corresponding deposition chamber to coat the first film layer, and at the same time, gas washing and vacuumizing are performed on the isolation chamber, until a vacuum degree and a process gas in the isolation chamber are consistent with those in the first process chamber;
after the first film layer is coated, the gate valve leading to the isolation chamber and the gate valve leading to the first process chamber are opened, each layer of the carrier plates after coating the first film layer is stacked onto the stack lifting mechanism in the isolation chamber by the stack lifting mechanism, at the same time, the carrier plates on the wafer inlet preheating chamber are conveyed on the first process chamber; the gate valves are closed, gas washing and vacuumizing are performed on the isolation chamber, until the vacuum degree and the process gas in the isolation chamber are consistent with those in the second process chamber; and at the same time, deposition electroplating is performed on the first process chamber; and
the gate valve leading to the second process chamber is opened, the multi-layer carrier plates in the isolation chamber are conveyed layer by layer continuously to a lower part of each deposition chamber of the second process chamber by the stack lifting mechanism; the gate valve is closed, gas washing and vacuumizing are performed on the isolation chamber, until the vacuum degree and the process gas in the isolation chamber are consistent with those in the first process chamber, and at the same time, each layer of the carrier plates in the second process chamber is lifted into corresponding deposition chamber to coat a second film layer, and several films are coated similarly until the process of the coating is completed.

15. The coating process according to claim 14, wherein in the step S3, gas washing and vacuumizing are firstly performed on the cooling wafer outlet chamber until a vacuum degree and a process gas are consistent with those in an endmost process chamber, then the gate valve leading to the cooling wafer outlet chamber is opened, each layer of the carrier plates after coating the film layer is stacked onto the stack lifting mechanism in the cooling wafer outlet chamber by the stack lifting mechanism; the gate valve is closed, gas washing is performed on the cooling wafer outlet chamber to remove the process gas, and cooling and vacuum breaking are performed to room pressure; then the gate valve leading to the unloader is opened, the multi-layer carrier plates are conveyed in batches onto the unloader, the gate valve is closed, gas washing and vacuumizing are performed on the cooling wafer outlet chamber until the vacuum degree and the process gas are consistent with those in the endmost process chamber, and at the same time, the silicon wafers are removed through the unloader.

16. The coating process according to claim 12, wherein two kinds of the process chambers are provided, which are an i-layer coating process chamber and a p-layer coating process chamber, respectively.

17. The coating process according to claim 12, wherein the number of deposition chambers of the i-layer coating process chamber and the number of deposition chambers of the p-layer coating process chamber are equal.

18. The coating process according to claim 17, wherein the number of deposition chambers of the i-layer coating process chamber and the number of deposition chambers of the p-layer coating process chamber are both four.

19. The coating process according to claim 12, wherein the one-stop coating module further comprises several evacuation pump sets, wherein one evacuation pump set communicates with one or more deposition chambers in the same process chamber.

20. The coating process according to claim 12, wherein the one-stop coating module further comprises several evacuation pump sets, wherein the wafer inlet-outlet stacking chamber comprises a chamber body, a carrier-plate transmission mechanism, a stack lifting mechanism and a vacuum generator, wherein the carrier-plate transmission mechanism is provided at two sides of the chamber body; the stack lifting mechanism is provided in the wafer inlet preheating chamber in a vertically movable manner, the stack lifting mechanism is provided with several support spacers for placing the carrier plates, the support spacers are each provided with a heating plate or a cooling plate in a bottom, and the support spacers, the heating plates and the cooling plates are provided with avoidance regions for avoiding the carrier-plate transmission mechanism; when the stack lifting mechanism is lowered to a lowest point, the carrier-plate transmission mechanism is located above an uppermost support spacer, and when the stack lifting mechanism is lifted to a highest point, the carrier-plate transmission mechanism is located below a lowermost support spacer; and the vacuum generator is provided outside the chamber body.
